(19) United States
(12) Patent Application Publication
(10) Pub. No.: US 2008/0116941 A1
(43) Pub. Date: May 22, 2008

(54) PEAK SIGNAL DETECTOR

(75) Inventors: Amal Ekbal, San Diego, CA (US); Chong U. Lee, San Diego, CA (US); David Jonathan Julian, San Diego, CA (US); Wei Xiong, San Diego, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 11/560,780

(22) Filed: Nov. 16, 2006

(51) Int. Cl. G01R 19/00; H03M 1/00; H04N 11/02

(52) U.S. Cl. 327/58; 341/132; 375/240.29

(57) ABSTRACT

A matched filter and peak detector identify peaks of a received signal. The peak detector may detect peaks during a fixed or adjustable time window. The peaks may be used as a preliminary decision (e.g., soft decision) for subsequent receiver decoding operations. The detector may be used to detect high bandwidth signals such as ultra-wide band signal pulses yet consume relatively minimal power.

### BACKGROUND

1. Field

This application relates generally to communications, and to detecting at least one peak of a signal.

2. Background

In a typical communication system a transmitter sends data to a receiver via a communication medium. For example, a wireless device may send data to another wireless device via radio frequency (“RF”) signals that travel through the air. Typically, the signals will be distorted after passing through the communication medium. To compensate for this distortion, the transmitter and the receiver may encode the signals before transmission and decode the received signals, respectively.

In some applications data may be encoded as a stream of signals each of which has a given amplitude, polarity and position in time. For example, a pulse position modulation scheme involves sending a series of pulses where the position of each pulse in time is modulated according to the particular data value that pulse represents. Conversely, a phase shift keying modulation scheme may involve sending a series of pulses where the polarity (e.g., +1 or −1) of each pulse is modulated according to the particular data value that pulse represents.

To recover data represented by such pulses, a typical receiver attempts to sample the received signals at appropriate times such that the sampling will obtain the true value of the pulses. In practice, however, the sampling circuitry of the receiver operates off of a clock signal that is different than the clock signal that was used by the transmitter to transmit the signals. As a result, the receiver may not have sufficient information regarding the timing of the transmitted signals to sample the received signals at the optimum point in time. Various techniques have been developed in an attempt to address such timing issues.

In a typical coherent matched filter detector, a received signal is fed through a matched filter and the output of the filter is sampled to recover the value of the received signal. Here, an attempt is made to sample the output of the filter at a peak value to obtain optimum signal-to-noise ratio performance. The detector may therefore employ a timing loop that generates a clock to control when a sampling circuit samples the output of the filter. In practice, however, timing jitter in the sampling clock tends to degrade the performance of the data recovery process.

Problems relating to jitter may be particularly pronounced in systems such as ultra-wide band transceivers that employ pulses of a very short time duration (e.g., on the order of the few nanoseconds). For example, when a body area network or a personal area network is implemented using ultra-wide band channels, channel delay spreads caused by the medium may be on the order of several tens of nanoseconds. If the signal carrier is several GHz and coherent or differentially coherent detection is used, timing jitter on the order of 20 to 40 picoseconds may result in a performance loss of several dB. Consequently, a detector may need to employ an extremely accurate time tracking loop to obtain an acceptable level of data recovery performance. In practice, such a mechanism may be relatively complicated and may consume a relatively large amount of power.

However, many applications require that transceiver components consume as little power as possible. For example, devices used in body area networks and personal area networks are typically wireless devices. In such devices it is generally desirable to keep power consumption to a minimum.

Some detector schemes for low-power applications use a non-coherent energy detector to detect a signal. For example, a receiver may include a matched filter followed by an energy detector (e.g., providing squaring and integration functions) that detects the energy output by the matched filter. Here, a windowing mechanism may be added at the output of the coherent matched filter detector to mitigate the effect of timing jitter. Such an approach may, however, result in a performance loss on the order of 3 dB.

In view of the above, many conventional data detection techniques may not be acceptable for some applications. For example, such techniques may not provide sufficient performance, may consume too much power or may not operate effectively at high data rates.

### SUMMARY

A summary of selected aspects of the disclosure follows. For convenience, one or more aspects may be referred to herein simply as “an aspect” or “aspects.”

In some aspects signals are processed to extract data from the signals. For example, a received signal may be filtered and processed to derive at least one peak value from the signal.

In some aspects a filter (e.g., a matched filter) and a peak detector combination is used to identify peaks of a received signal. Here, an input signal is provided to the filter and the output of the filter is provided to an input of the peak detector. The peak detector may then detect one or more peaks associated with each pulse of the received signal. The detected peak value(s) may be used as a preliminary decision (e.g., soft decision) for subsequent receiver decoding operations. Advantageously, this combination may be used to detect peaks of high bandwidth signals while consuming a relatively small amount of power.

Some aspects may employ a windowed peak detector. For example, the peak detector may be turned on and turned off in accordance with a time window. In some aspects the position of the window in time and/or the width of the time window may be adjusted to improve peak detection.

In some aspects, a low-power peak detector may employ capacitors that are controllably charged or discharged during the time window to provide signals indicative of one or more peaks. For example, one capacitor may provide a signal indicative of a positive peak while another capacitor provides a signal indicative of a negative peak.

In some aspects peak detection may be provided for relatively high-speed signals. For example, peak detection may be used to identify peaks of ultra-wide band signal pulses.

### BRIEF DESCRIPTION OF THE DRAWINGS

These and other features, aspects and advantages of the disclosure will be more fully understood when considered with respect to the following detailed description, appended claims and accompanying drawings, wherein:

FIG. 1 is a simplified block diagram of several exemplary aspects of a receiver employing a filter and a peak detector;

FIG. 2 is a flowchart of several exemplary aspects of operations that may be performed to detect a received signal;

FIG. 3 is a simplified diagram illustrating an example of a peak detection time window and detection of a peak of a signal;

FIG. 4 is a simplified diagram illustrating an example of a peak detection time window and detection of peaks of a signal;

FIG. 5 is a simplified diagram illustrating an example of several detection time windows for a pulse position modulated signal;

FIG. 6 is a simplified diagram illustrating several exemplary aspects of a peak detector;

FIG. 7 is a simplified diagram illustrating several exemplary aspects of a peak detector; and

FIG. 8 is a simplified block diagram of several exemplary aspects of a receiver employing filter and peak detector components.

In accordance with common practice the various features illustrated in the drawings may not be drawn to scale. Accordingly, the dimensions of the various features may be arbitrarily expanded or reduced for clarity. In addition, some of the drawings may be simplified for clarity. Thus, the drawings may not depict all of the components of a given apparatus or method. Finally, like reference numerals may be used to denote like features throughout the specification and figures.

### DETAILED DESCRIPTION

Various aspects of the disclosure are described below. It should be apparent that the teachings herein may be embodied in a wide variety of forms and that any specific structure and/or function disclosed herein is merely representative. Based on the teachings herein one skilled in the art should appreciate that an aspect disclosed herein may be implemented independently of any other aspects and that two or more of these aspects may be combined in various ways. For example, an apparatus may be implemented and/or a method practiced using any number of the aspects set forth herein. In addition, an apparatus may be implemented and/or a method practiced using other structure and/or functionality in addition to or other than one or more of the aspects set forth herein.

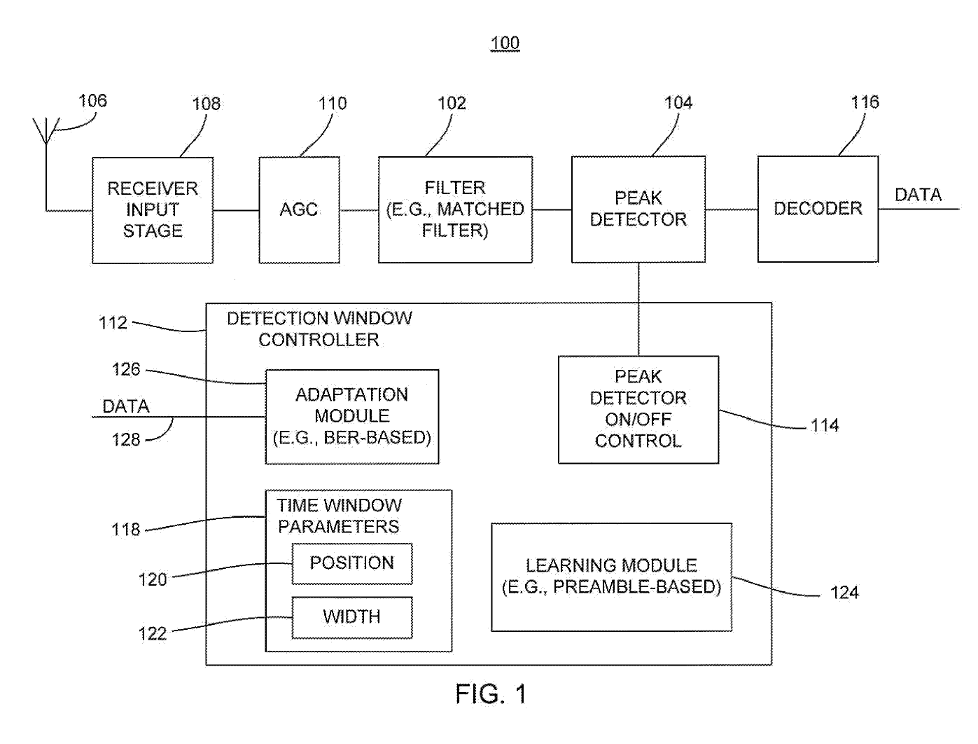

FIG. 1 illustrates several aspects of a receiver 100 including a filter 102 and a peak detector 104 for extracting data from a received signal. The peak detector 104 detects one or more peaks in a signal output by the filter. In some aspects, the peak detector 104 may detect peaks within a window of time. This window of time may be fixed or may be adaptively changed.

In some aspects the filter 102 may comprise a matched filter. For example, the filter may be matched (e.g., to some degree) to a transmitted waveform or to a received waveform. For convenience, the discussion that follows may simply refer to a matched filter. It should be appreciated, however, that other types of filters may be employed in accordance with the teachings herein.

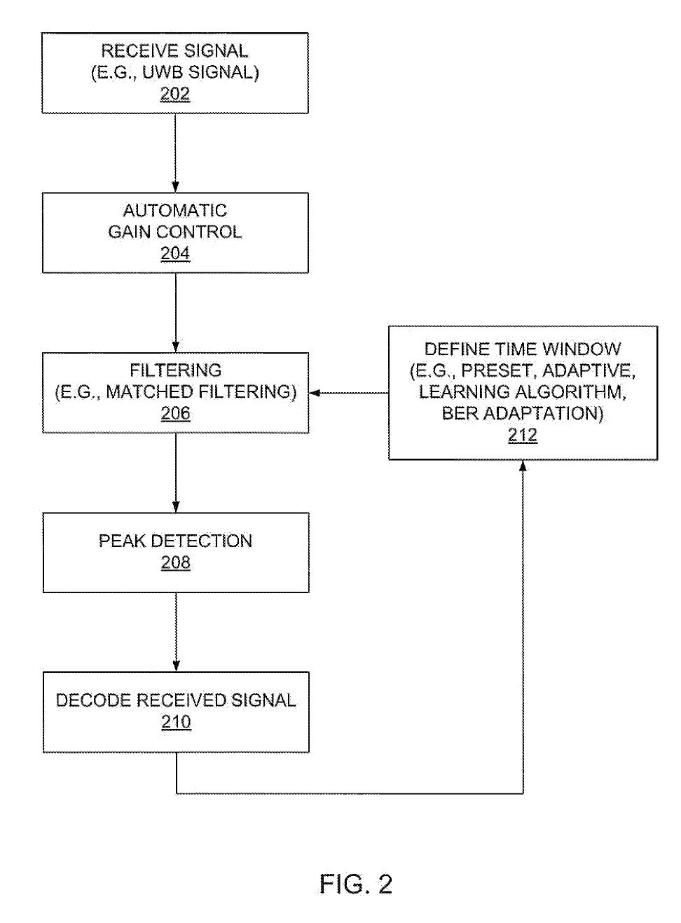

Exemplary operations that may be used to extract data from a received signal using a matched filter and peak detector combination will now be discussed in conjunction with the flowchart of FIG. 2. For convenience, the operations of FIG. 2 (and any other flowchart herein) may be described as being performed by specific components. It should be appreciated, however, that these operations may be performed in conjunction with and/or by other components.

As represented by block 202, the receiver 100 receives an input signal from a communication medium. The receiver 100 may include an antenna 106 and an associated receiver input stage 108 for receiving radio frequency signals such as, for example, ultra-wide band (“UWB”) signals. In some aspects an ultra-wide band signal may be defined as a signal having a fractional bandwidth on the order of 20% and/or more or having a bandwidth on the order of 500 MHz or more. It should be appreciated that the teachings herein may be applicable to other types of received signals having various frequency ranges and bandwidths. Moreover, such signals may be received via a wired or wireless medium.

As represented by block 204, the received signals may be provided to an automatic gain control (“AGC”) circuit 110. The automatic gain control 110 may adjust the gain of the received signal to avoid providing a saturated signal to the matched filter 102 and to mitigate circuit noise.

As represented by block 206, the gain control signal is provided to the matched filter 102. The characteristics of the matched filter 102 may, in part, compensate for distortion imparted on the received signal by the communication medium.

The matched filter 102 may be implemented in a variety of ways. For example, a transmitted reference system employs a reference pulse followed, in accordance with a known delay, by a data pulse. In such a system a matched filter 102 may comprise a delay element that delays the reference pulse by the known delay and a multiplier that multiplies the delayed reference pulse with the data pulse. The output of the multiplier may then be provided to an integrator (e.g., a sliding window integrator, an infinite impulse response integrator or some other suitable integrator). In this way, the phase of the reference pulse may be compared to the phase of the data pulse. For example, if the reference pulse and the data pulse are in-phase, a positive peak may result. Conversely, if the reference pulse and the data pulse are 180 degrees out-of-phase, a negative peak may result. This configuration tends to compensate for the effect of the channel on the data pulse because the reference pulse was subjected to essentially the same channel conditions as the data pulse.

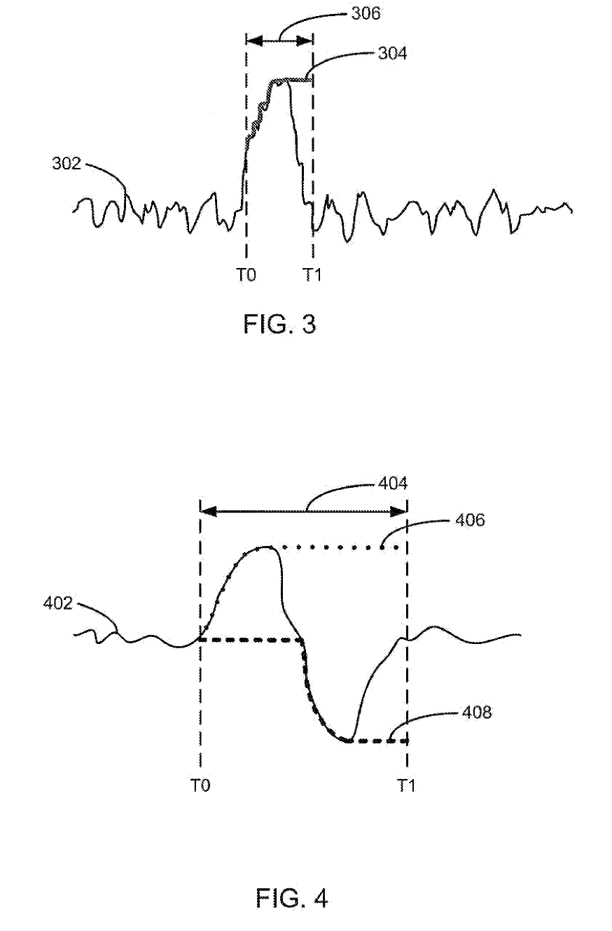

As represented by block 208, the peak detector 104 detects one or more peaks in the signal output by the matched filter 102. FIG. 3 illustrates an example of a peak detection operation on a signal 302. In this example, the peak detection operation commences a time T0. For example, the output of the peak detector 104, as represented by a shaded line 304, may follow the rising amplitude of the signal 302. In addition, the output 304 will maintain the maximum amplitude value attained since time T0 in the event the amplitude of the signal 302 decreases. In other words, when the amplitude of the signal 302 decreases the line 304 remains at a constant level. Thus, the peak detector 104 may maintain its output at the detected peak value until it is reset. A peak detector circuit as taught herein may thus provide a relatively jitter-free signal representative of the peak value of a received signal.

In some aspects, the peak detection operation may be performed during a given period of time. For example, referring again to FIG. 1 the transmitter 100 may include a detection window controller 112 that is adapted to control the operation of the peak detector 104. Referring to FIG. 3, the controller 112 may reset the output of the peak detector 104 at some time prior to time T0. A peak detector on/off control 114 may then activate the peak detector 104 at time T0 and deactivate the peak detector 104 at time T1 thereby defining a time window as represented by the arrows 306.

In some applications, as long as a peak occurs within the time window the exact position of the peak may not be critical. Here, the time window may be defined such that peak detection commences at an appropriate time and occurs for a sufficient amount of time to enable detection of the desired signal peak while rejecting spurious peaks (e.g., noise) that may be present in the received signal before and/or after the peak. Consequently, timing jitter problems that may be present in other implementations that attempt to sample an input signal at its peak value may be avoided or substantially reduced through the use of such a peak detector circuit as taught herein. Moreover, this may be accomplished without the use of a highly precise timing loop since the position in time of the peak detector time window may not need to be precisely controlled.

The peak detection operation may be performed in a variety of ways and on various types of signals. For example, FIG. 4 illustrates an aspect where the peak detector 104 detects positive and negative peaks of a signal 402 (e.g., a phase shift keying modulated signal). Again, the peak detection operation commences a time T0 and stops at time T1 in accordance with a time window as represented by arrows 404. Also, an output of the peak detector 104 as represented by a dotted line 406 tracks the maximum amplitude of the signal 402. In addition, another output of the peak detector 104 as represented by the dashed line 408 tracks the minimum amplitude of the signal 402. Accordingly, the peak detector 104 may output more than one peak signal (e.g., signals 406 and 408).

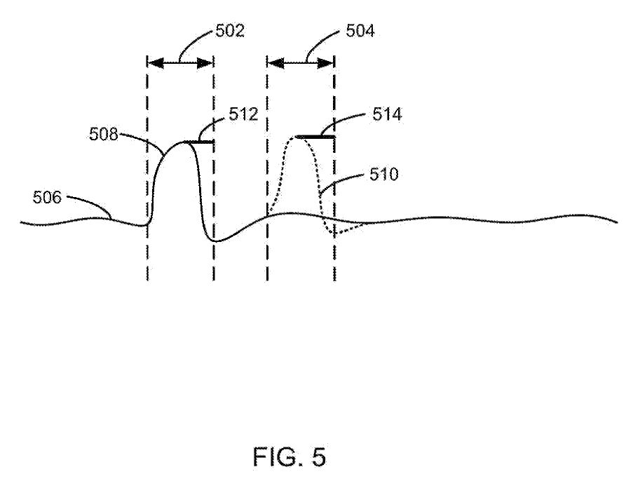

FIG. 5 illustrates another aspect where the peak detector 104 may be adapted to detect peaks in a plurality of time windows as represented by the arrows 502 and 504. Such a configuration may be used, for example, to detect peaks of a pulse position modulated signal 506. Here, the time windows 502 and 504 may correspond to expected positions of pulses representing a particular data value. For example, when the signal 506 has a pulse 508 in the time window 502 a binary 0 may be indicated. Conversely, as represented by the dashed pulse 510, when the signal has a pulse in the time window 502 a binary 1 may be indicated. Thus, the peak detector 104 may be turned on during the time windows 502 and 504 to determine a peak 512 or 514 of any pulses appearing during these time periods.

Referring again to FIG. 2, as represented by block 210 the peak signal(s) output by the peak detector 104 may be used to determine the particular data value represented by the received signal. For example, depending on the specific modulation scheme used, the peak signals may be used to form a decision variable. In the case where the modulation scheme is un-coded binary phase shift keying, a comparator may be used to detect the data in the received signal. Alternatively, in some aspects the peak signal(s) may be used as a preliminary decision (e.g., a soft decision) for a decoder 116 or some other suitable processing component in the receiver 100.

As represented by block 212, at some point in time the time window for the peak detector is defined. The time window for the peak detector may be fixed or may be adaptively changed. Referring again to FIG. 1, in some aspects window definition parameters 118 indicating a position in time (e.g., a starting time) 120 of the time window and a width 122 of the time window may be maintained in the receiver 100. For example, in cases where the time window is fixed, the window definition parameters 118 may be hard-wired (e.g., stored in a read-only memory) into the receiver 100. Alternatively, in cases where the time window is fixed or is not fixed the window definition parameters 118 may be stored in a data memory.

In the case of a fixed time window, the starting time and width of the time window may be selected in various ways. For example, these parameters may be selected based on simulations, empirical tests, characteristics of the peak detector, channel conditions, characteristics of received signals, or some other factor(s) that may help to identify a time position and width of a time window that leads to substantially optimum peak detection performance. Some of these operations may be performed before the receiver commences receiving a signal. For example, in some cases these parameters may be programmed into the receiver 100 upon manufacture or initialization of the receiver 100.

In some cases these parameters may be determined after the receiver 100 has commenced receiving signals. For example, the controller 112 may include a learning module 124 that presets the window definition parameters 118 based on, in some aspects, a preamble of a received signal. In a typical scenario a transmitter transmits one or more preambles including a known data sequence (e.g., based on the addresses of the transmitter and receiver). While a preamble is been received, the learning module 124 may test several hypotheses of the window definition parameters 118. For example, the learning module 124 may set the window definition parameters 118 to a given set of parameters then perform one or more tests to determine how effectively the receiver is deriving the known data sequence from the received signal. The learning module 124 may then perform a similar operation using different sets of window definition parameters. Based on the results of these tests, the learning module 124 may select a set of parameters that provides the best receiver operation. In this way, the window definition parameters 118 may be preset to nominal values that are selected by taking into account the current conditions in the communication medium (e.g., channel) through which signals are received.

In some aspects the controller 112 may adaptively control the time window. Here, the controller 112 may include an adaptation module 126 that analyzes received data or some other suitable information to identify a set of window definition parameters 118 that results in substantially optimum receiver operation. For example, the adaptation module 126 may analyze a bit error rate (“BER”) associated with received data 128 to adjust the window definition parameters 118. Here, the module 126 may identify a given set of window definition parameters 118 that results in the lowest bit error rate for the received data 128 (e.g., the data recovered by the decoder 116). Alternatively, the module 126 may analyze a statistical value of peak values, such as a mean or median. The module 126 may then select the window resulting in the best statistical value, such as the largest absolute mean peak. Operations such as these may be performed when the receiver 100 is receiving test data (e.g., a preamble) or non-test data (e.g., user traffic).

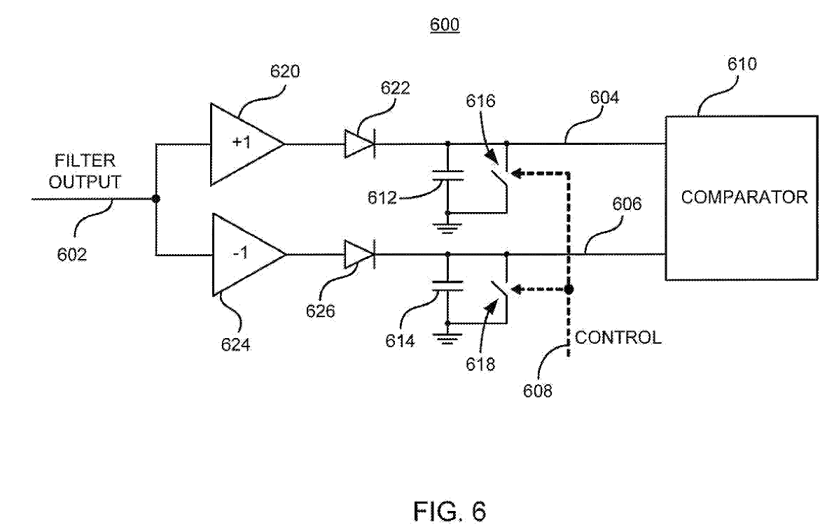

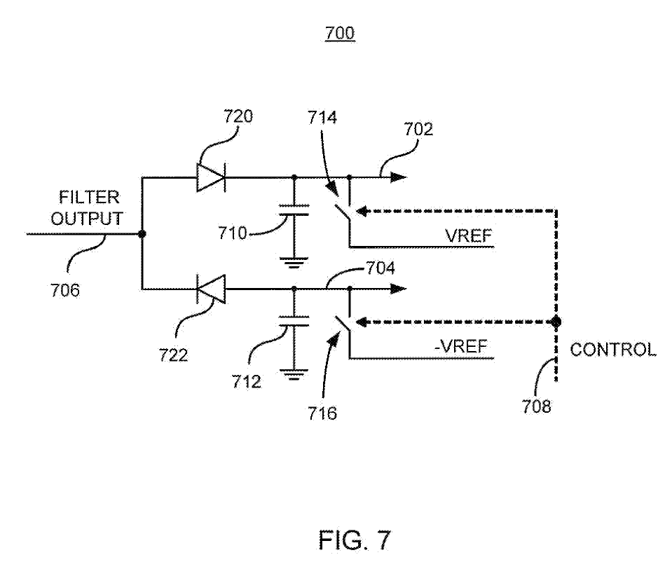

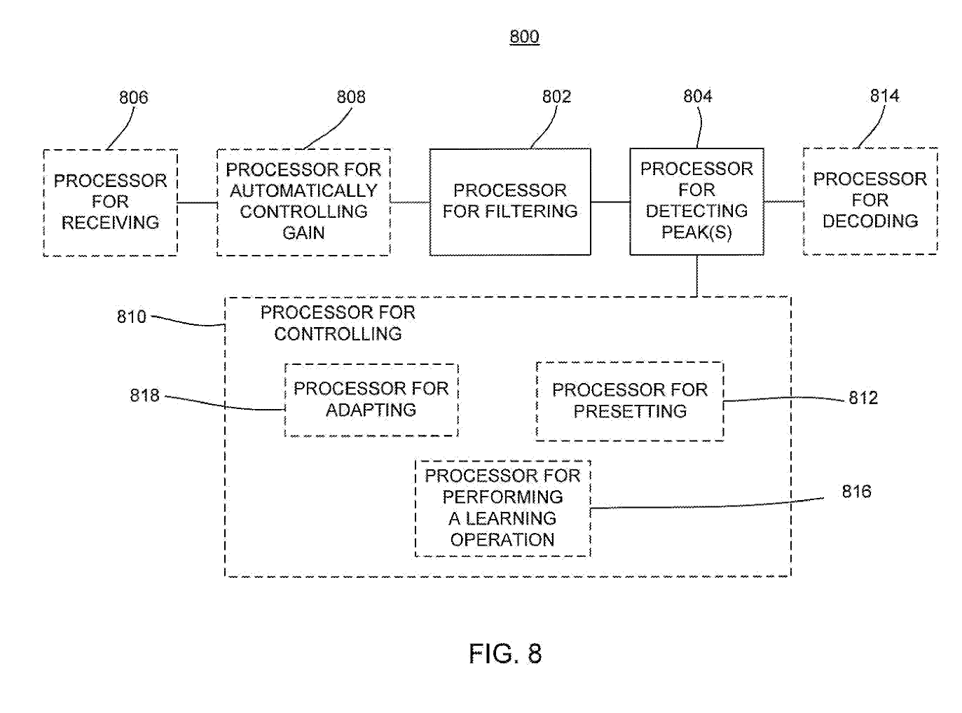

A peak detector may be implemented in a variety of ways. FIGS. 6 and 7 illustrate examples of low power peak detectors 600 and 700 that may be used to detect positive and/or negative peaks of a received signal. These detectors may be used to detect peaks in systems that employ very narrow pulses (e.g., ultra-wide band systems). In addition, these detectors may be coupled to and/or decoupled from a matched filter output signal to perform peak detection operations within a desired time window.

Referring to FIG. 6, the peak detector 600 processes a signal 602 output by a matched filter (not shown) to provide an output signal 604 representative of a positive peak of the signal 602 and an output signal 606 representative of a negative peak of the signal 602. A control signal 608 controls the operation of the peak detector 600, for example, in accordance with a peak detector time window.

The positive and negative peak signals 604 and 606 are used to derive a data value from the signal 602. In some applications the signals 604 and 606 are used as a soft decision for a downstream decoder (not shown). Alternatively, as shown in FIG. 6 a comparator 610 use the positive and negative peak signals 604 and 606 to generate a decision variable. For example, as discussed above when the signal 602 is an un-coded binary phase shift keying modulated signal, the output of the comparator may provide the final value of the detected signal.

The peak detector 600 includes a pair of capacitors 612 and 614 adapted to store charges to generate the positive and negative peak signals 604 and 606, respectively. A pair of switches 616 and 618 controlled by the control signal 608 may be closed to discharge the capacitors 612 and 614 to, in effect, reset the peak detector 600. The switches 616 and 618 are then opened to commence the peak detection operation (e.g., at time T0 in FIG. 3).

The signal 602 is coupled to the capacitor 612 via a buffer 620 and a diode 622. The buffer 620 is a non-inverting buffer (as represented by the designation “+1”). Typically, the diode 622 will be adapted to provide a relatively low voltage drop. For example, the diode 622 may comprise a Schottky diode.

Through the operation of the buffer 620 and the diode 622, when the signal 602 rises to a level that is above (e.g., is more positive than) the existing voltage on the capacitor 612 (e.g., 0 V after the capacitor 612 is discharged) the diode 622 will be forward-biased. As a result, current will flow through a circuit including the capacitor 612, the diode 622 and the buffer 620. This current flow causes the capacitor 612 to charge to a voltage level that substantially approximates (e.g., is slightly less than) the positive voltage level of the signal 602.

In the event the voltage level of the signal 602 drops below a prior voltage level to which the capacitor 612 has been charged (e.g., a prior positive peak value), the diode 622 will become reverse-biased. The diode 622 will thus present an open circuit preventing current flow through the diode 622. As a result, the capacitor 612 will maintain its charge at the prior voltage level because there is no current path through which the capacitor 612 can discharge. The signal 604 provided by the capacitor 612 thus corresponds to a positive peak of the signal 602.

The signal 602 is coupled to the capacitor 614 via a buffer 624 and a diode 626. The buffer 624 is an inverting buffer (as represented by the designation “−1”). The diode 626 also may be adapted to provide a relatively low voltage drop.

Through the operation of the buffer 624 and the diode 626, when the signal 602 drops to a level that is below (e.g., is more negative than) the existing voltage on the capacitor 612 (e.g., 0 V after the capacitor 612 is discharged) the diode 626 will be forward-biased due to the inversion provided by the buffer 624. As a result, current will flow through a circuit including the capacitor 614, the diode 626 and the buffer 624. This current flow causes the capacitor 614 to charge to a voltage level that substantially approximates (e.g., is slightly less than an absolute value of) the negative voltage level of the signal 602. In the event the magnitude of the voltage level of the signal 602 decreases (e.g., the absolute value of the signal 602 becomes less than) a prior voltage level to which the capacitor 614 has been charged (e.g., representing a prior negative peak value), the diode 626 will become reverse-biased. The diode 626 will thus present an open circuit preventing current flow through the diode 626. As a result, the capacitor 614 will maintain its charge at the prior voltage level because there is no current path through which the capacitor 614 can discharge. The signal 606 provided by the capacitor 614 thus corresponds to a negative peak of the signal 602.

Referring now to FIG. 7, the detector 700 generates a positive peak signal 702 and a negative peak signal 704 from a matched filter output signal 706 without the use of an inverting buffer as is used in FIG. 6. The operation of the peak detector 700 is controlled by a control signal 708 that is based on, for example, a peak detector time window.

The peak detector 700 includes a pair of capacitors 710 and 712 adapted to store charges to generate the positive and negative peak signals 702 and 704, respectively. The capacitor 710 will charge to a peak positive voltage level when the signal 706 is more positive than a positive reference voltage (VREF). The capacitor 712 will charge to a peak negative voltage level when the signal 706 is more negative than a negative reference voltage (−VREF).

A pair of switches 714 and 716 controlled by the control signal 708 is closed to reset the peak detector 600. In this case closing the switches 714 and 716 sets the capacitors 710 and 712 to voltage levels equal to VREF and −VREF, respectively. The switches 714 and 716 are opened to commence the peak detection operation (e.g., at time T0 in FIG. 3).

The signal 706 is coupled to the capacitor 710 via a diode 720 and to the capacitor 712 via a diode 722. The diodes 720 and 722 also will typically be adapted to provide a relatively low voltage drop (e.g., they may comprise Schottky diodes).

After the peak detector 700 has been reset, when the signal 706 rises to a level that is above (e.g., is more positive than) VREF the diode 720 will be forward-biased. As a result, current will flow through a circuit including the capacitor 710 and the diode 720. This current flow causes the capacitor 710 to charge to a voltage level that substantially approximates (e.g., is slightly less than) the positive voltage level of the signal 706.

In the event the voltage level of the signal 706 drops below a prior voltage level to which the capacitor 710 has been charged (e.g., a prior positive peak value), the diode 720 will become reverse-biased. As a result the capacitor 710 will maintain its charge at the prior voltage level because there is no current path through which the capacitor 710 can discharge. The signal 702 provided by the capacitor 710 thus corresponds to a positive peak of the signal 706.

In contrast, when the signal 706 drops to a level that is below (e.g., is more negative than) −VREF the diode 722 will be forward-biased. As a result, current will flow through a circuit including the capacitor 712 and the diode 722. This current flow causes the capacitor 712 to charge to a negative voltage level that substantially approximates (e.g., is slightly more positive than) the negative voltage level of the signal 706.

In the event the voltage level of the signal 706 rises above (e.g., is more positive than) a prior negative voltage level to which the capacitor 712 has been charged (e.g., a prior negative peak value), the diode 722 will become reverse-biased. The capacitor 712 will then maintain its charge at the prior voltage level due to the absence of a discharge path. The signal 704 provided by the capacitor 712 thus corresponds to a negative peak of the signal 706.

It should be appreciated that the teachings herein may be applicable to a wide variety of applications other than those specifically mentioned above. For example, the teachings herein may be applicable to systems utilizing different bandwidths, signal types (e.g., shapes), or modulation schemes. Also, peak detectors constructed in accordance with these teachings may be implemented using various circuits including circuits other than those specifically described herein.

The teachings herein may be incorporated into a variety of devices. For example, one or more aspects taught herein may be incorporated into a phone (e.g., a cellular phone), a personal data assistant (“PDA”), an entertainment device (e.g., a music or video device), a headset, a microphone, a biometric sensor (e.g., a heart rate monitor, a pedometer, an EKG device, etc.), a user I/O device (e.g., a watch, a remote control, etc.), a tire pressure monitor, or any other suitable communicating device. Moreover, these devices may have different power and data requirements. Advantageously, the teachings herein may be adapted for use in low power applications (e.g., through the use of a low power circuit for peak detection). In addition, these teaching may be incorporated into an apparatus supporting various data rates including relatively high data rates (e.g., through the use of a circuit adapted to process high-bandwidth pulses).

The components described herein may be implemented in a variety of ways. For example, referring to FIG. 8, a receiver 800 includes components 802, 804, 806, 808, 810, 812, 814, and 816 that may correspond to components 102, 104, 108, 110, 112, 112, 126, and 124 in FIG. 1. FIG. 8 illustrates that in some aspects these components may be implemented via appropriate processor components. These processor components may in some aspects be implemented, at least in part, using structure as taught herein. In some aspects the components represented by dashed boxes are optional.

In addition, the components and functions represented by FIG. 8, as well as other components and functions described herein, may be implemented using any suitable means. Such means also may be implemented, at least in part, using corresponding structure as taught herein. For example, in some aspects means for filtering may comprise a filter, means for detecting may comprise a detector, means for automatically controlling gain may comprise an automatic gain control, means for decoding may comprise a decoder, means for performing a learning operation may comprise a learning module, means for presetting may comprise a controller, means for controlling may comprise a controller, means for adapting may comprise an adaptation module, and means for receiving may comprise a receiver. One or more of such means also may be implemented in accordance with one or more of the processor components of FIG. 8.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, processors, means, circuits, and algorithm steps described in connection with the aspects disclosed herein may be implemented as electronic hardware, various forms of program or design code incorporating instructions (which may be referred to herein, for convenience, as “software” or a “software module”), or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

It is understood that the specific order or hierarchy of steps in the processes disclosed is an example of exemplary approaches. Based upon design preferences, it is understood that the specific order or hierarchy of steps in the processes may be rearranged while remaining within the scope of the present disclosure. The accompanying method claims present elements of the various steps in a sample order, and are not meant to be limited to the specific order or hierarchy presented.

The steps of a method or algorithm described in connection with the aspects disclosed herein may be embodied directly in hardware, in a software module executed by a processor, or in a combination of the two. A software module (e.g., including executable instructions and related data) and other data may reside in a data memory such as RAM memory, flash memory, ROM memory, EPROM memory, EEPROM memory, registers, a hard disk, a removable disk, a CD-ROM, or any other form of computer-readable storage medium known in the art. An exemplary storage medium may be coupled to a machine such as, for example, a computer/processor (which may be referred to herein, for convenience, as a “processor”) such the processor can read information (e.g., code) from and write information to the storage medium. An exemplary storage medium may be integral to the processor. The processor and the storage medium may reside in an ASIC. The ASIC may reside in user equipment. In the alternative, the processor and the storage medium may reside as discrete components in user equipment.

The previous description of the disclosed aspects is provided to enable any person skilled in the art to make or use the present disclosure. Various modifications to these aspects will be readily apparent to those skilled in the art, and the generic principles defined herein may be applied to other aspects without departing from the spirit or scope of the disclosure. Thus, the present disclosure is not intended to be limited to the aspects shown herein but is to be accorded the widest scope consistent with the principles and novel features disclosed herein.

What is claimed is:

1. An apparatus for detecting a peak signal, comprising:
a filter adapted to filter an input signal; and
a peak detector, coupled to an output of the filter, and adapted to generate at least one output signal indicative of at least one peak of the filtered input signal.

2. The apparatus of claim 1, wherein the filter further comprises a matched filter.

3. The apparatus of claim 1, further comprising an automatic gain control adapted to: control amplitude of the input signal, reduce noise associated with the input signal, or control amplitude of the input signal and reduce noise associated with the input signal.

4. The apparatus of claim 1, further comprising a decoder adapted to use the at least one output signal as a preliminary decision signal to decode data encoded in the input signal.

5. The apparatus of claim 1, wherein the at least one peak further comprises a positive peak and a negative peak.

6. The apparatus of claim 1, further comprising a detection window controller, adapted to control the peak detector to detect the at least one peak within a time window.

7. The apparatus of claim 6, wherein the detection window controller is further adapted to define a fixed position in time and a fixed width of the time window.

8. The apparatus of claim 6, wherein the detection window controller is further adapted to perform a learning operation based on a preamble of a received signal to define the time window.

9. The apparatus of claim 6, wherein the detection window controller is further adapted to preset, in accordance with a condition in a communication channel through which the input signal passes, a position in time of the time window and a width of the time window.

10. The apparatus of claim 6, wherein the detection window controller is further adapted to adaptively control, in accordance with a received signal, a position in time of the time window, a width of the time window, or a position in time and a width of the time window.

11. The apparatus of claim 6, wherein the detection window controller is further adapted to adapt, in accordance with a bit error rate or statistical peak value of data recovered from the input signal: a position in time of the time window, a width of the time window, or a position in time and a width of the time window.

12. The apparatus of claim 6, wherein the peak detector further comprises a plurality of capacitors each of which is adapted to be either charged or discharged during the time window, wherein each capacitor is further adapted to generate a positive peak signal or a negative peak signal to provide the at least one output signal.

13. The apparatus of claim 12, further comprising a plurality of switches each of which is adapted to, prior to a starting time of the time window, either charge or discharge at least one of the capacitors.

14. The apparatus of claim 13, wherein each of the switches is further adapted to, prior to the starting time of the time window, either charge or discharge at least one of the capacitors to a reference voltage.

15. The apparatus of claim 13, further comprising a plurality of diodes each of which is adapted to control current flow to either charge or discharge at least one of the capacitors to generate the positive and negative peak signals.

16. The apparatus of claim 1, wherein the input signal further comprises an ultra-wide band signal having a fractional bandwidth on the order of 20% or more or having a bandwidth on the order of 500 MHz or more.

17. The apparatus of claim 1, wherein the filter and the peak detector are further adapted to reduce jitter effects associated with the input signal.

18. The apparatus of claim 1, wherein the apparatus is implemented in a receiver adapted to receive the input signal via a wireless communication channel.

19. The apparatus of claim 1, wherein the apparatus is implemented in at least one of the group consisting of: a headset, a microphone, a biometric sensor, a heart rate monitor, a pedometer, an EKG device, a user I/O device, a watch, a remote control, and a tire pressure monitor.

20. A method of detecting a peak signal, comprising:
filtering an input signal; and
detecting at least one peak of the filtered input signal to provide at least one output signal.

21. The method of claim 20, wherein the input signal is filtered in accordance with a matched filter.

22. The method of claim 20, further comprising automatically controlling gain of the input signal.

23. The method of claim 20, further comprising using the at least one output signal as a preliminary decision signal to decode data encoded in the input signal.

24. The method of claim 20, wherein the at least one peak further comprises a positive peak and a negative peak.

25. The method of claim 20, wherein the at least one peak is detected within a time window.

26. The method of claim 25, further comprising performing a learning operation based on a preamble of a received signal to define the time window.

27. The method of claim 25, further comprising presetting, in accordance with a condition in a communication channel through which the input signal passes, a position in time of the time window and a width of the time window.

28. The method of claim 25, further comprising controlling at least one of the group consisting of: a position in time of the time window and a width of the time window.

29. The method of claim 25, further comprising adapting, in accordance with a received signal, at least one of the group consisting of: a position in time of the time window and a width of the time window.

30. The method of claim 25, further comprising adapting, in accordance with a bit error rate of data recovered from the input signal, at least one of the group consisting of: a position in time of the time window and a width of the time window.

31. The method of claim 20, further comprising receiving the input signal via a wireless communication channel.

32. The method of claim 20, wherein the input signal further comprises an ultra-wide band signal having a fractional bandwidth on the order of 20% or more or having a bandwidth on the order of 500 MHz or more.

33. The method of claim 20, wherein the method is performed in at least one of the group consisting of: a headset, a microphone, a biometric sensor, a heart rate monitor, a pedometer, an EKG device, a user I/O device, a watch, a remote control, and a tire pressure monitor.

34. An apparatus for detecting a peak signal, comprising:
means for filtering an input signal; and
means for detecting at least one peak of the filtered input signal to provide at least one output signal.

35. The apparatus of claim 34, wherein the means for filtering further comprises a matched filter.

36. The apparatus of claim 34, further comprising means for automatically controlling gain of the input signal.

37. The apparatus of claim 34, further comprising means for decoding data encoded in the input signal by using the at least one output signal as a preliminary decision signal.

38. The apparatus of claim 34, wherein the at least one peak further comprises a positive peak and a negative peak.

39. The apparatus of claim 34, wherein the at least one peak is detected within a time window.

40. The apparatus of claim 39, further comprising means for performing a learning operation based on a preamble of a received signal to define the time window.

41. The apparatus of claim 39, further comprising means for presetting, in accordance with a condition in a communication channel through which the input signal passes, a position in time of the time window and a width of the time window.

42. The apparatus of claim 39, further comprising means for controlling at least one of the group consisting of: a position in time of the time window and a width of the time window.

43. The apparatus of claim 39, further comprising means for adapting, in accordance with a received signal, at least one of the group consisting of: a position in time of the time window and a width of the time window.

44. The apparatus of claim 39, further comprising means for adapting in accordance with a bit error rate of data recovered from the input signal, at least one of the group consisting of: a position in time of the time window and a width of the time window.

45. The apparatus of claim 34, further comprising means for receiving the input signal via a wireless communication channel.

46. The apparatus of claim 34, wherein the input signal further comprises an ultra-wide band signal having a fraction bandwidth on the order of 20% or more or having a bandwidth on the order of 500 MHz or more.

47. The apparatus of claim 34, wherein the apparatus is implemented in at least one of the group consisting of: a headset, a microphone, a biometric sensor, a heart rate monitor, a pedometer, an EKG device, a user I/O device, a watch, a remote control, and a tire pressure monitor.

48. A computer-program product for detecting a peak signal comprising:
a computer-readable medium comprising codes for causing a computer to:
filter an input signal; and
detect at least one peak of the filtered input signal to provide at least one output signal.

49. A processor for detecting a peak signal, the processor being adapted to:
filter an input signal; and
detect at least one peak of the filtered input signal to provide at least one output signal.
